(19) United States
(12) Patent Application Publication
(10) Pub. No.: US 2016/0081190 A1
(43) Pub. Date: Mar. 17, 2016

(54) PRINTED WIRING BOARD AND METHOD FOR MANUFACTURING THE SAME

(71) Applicant: IBIDEN CO., LTD., Ogaki (JP)

(72) Inventors: Yasushi INAGAKI, Ogaki (JP); Atsushi KONDO, Ogaki (JP); Hiroyuki NISHIOKA, Ogaki (JP); Noritaka YAMASHITA, Ogaki (JP)

(73) Assignee: IBIDEN CO., LTD., Ogaki (JP)

(21) Appl. No.: 14/851,789

(22) Filed: Sep. 11, 2015

(30) Foreign Application Priority Data
Sep. 12, 2014 (JP) 2014-185971

(51) Int. Cl. H05K 1/11; H05K 3/46; H05K 3/02

(52) U.S. Cl. CPC H05K 1/111; H05K 3/027; H05K 3/4644

(57) ABSTRACT

A printed wiring board includes a resin insulation layer, a conductive layer formed on a surface of the resin insulation layer and including NSMD pads, and a solder-resist layer formed on the resin insulation layer and having openings such that the openings are exposing the NSMD pads, respectively. The solder-resist layer includes a lower solder-resist layer formed on the surface of the resin insulation layer and an upper solder-resist layer formed on the lower solder-resist layer, and each of the openings has a lower opening portion formed in the lower solder-resist layer and an upper opening portion formed in the upper solder-resist layer such that the upper opening portion has a size which is greater than a size of the lower opening portion.

### CROSS-REFERENCE TO RELATED APPLICATIONS

The present application is based upon and claims the benefit of priority to Japanese Patent Application No. 2014-185971, filed Sep. 12, 2014, the entire contents of which are incorporated herein by reference.

### BACKGROUND OF THE INVENTION

1. Field of the Invention

The present invention relates to a printed wiring board having non-solder mask defined (NSMD) pads and to a method for manufacturing such a printed wiring board.

2. Description of Background Art

JP2006-074002A describes a method for mounting solder balls. Solder mask defined (SMD) pads are shown in JP2006-074002A. The entire contents of this publication are incorporated herein by reference.

### SUMMARY OF THE INVENTION

According to one aspect of the present invention, a printed wiring board includes a resin insulation layer, a conductive layer formed on a surface of the resin insulation layer and including NSMD pads, and a solder-resist layer formed on the resin insulation layer and having openings such that the openings are exposing the NSMD pads, respectively. The solder-resist layer includes a lower solder-resist layer formed on the surface of the resin insulation layer and an upper solder-resist layer formed on the lower solder-resist layer, and each of the openings has a lower opening portion formed in the lower solder-resist layer and an upper opening portion formed in the upper solder-resist layer such that the upper opening portion has a size which is greater than a size of the lower opening portion.

According to another aspect of the present invention, a method for manufacturing a printed wiring board includes forming an intermediate substrate including a resin insulation layer and a conductive layer such that the conductive layer is formed on a surface of the resin insulation layer and including NSMD pads, and forming a solder-resist layer on the resin insulation layer such that the solder-resist layer has openings exposing the NSMD pads, respectively. The forming of the solder-resist layer includes forming a lower solder-resist layer on the surface of the resin insulation layer and forming an upper solder-resist layer on the lower solder-resist layer such that each of the openings has a lower opening portion formed in the lower solder-resist layer and an upper opening portion formed in the upper solder-resist layer and having a size which is greater than a size of the lower opening portion.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIGS. 1(A) and 1(B) are cross-sectional views showing a printed wiring board according to an embodiment of the present invention;

FIG. 1(C) is a plan view showing an NSMD pad;

FIGS. 1(D) and 1(E) are enlarged views of a pad and a solder-resist layer surrounding the pad;

FIGS. 2(A)˜2(I) are cross-sectional views showing a method for manufacturing a printed wiring board according to an embodiment of the present invention;

FIGS. 2(J) and 2(K) are cross-sectional views showing examples of a solder-resist layer for forming an SMD pad;

FIGS. 3(A)˜3(G) are cross-sectional views showing another method for manufacturing a printed wiring board according to another embodiment of the present invention;

FIG. 3(H) is a cross-sectional view showing an example of a solder-resist layer for forming an SMD pad;

FIG. 4(A) shows NSMD pads;

FIG. 4(B) shows SMD pads;

FIG. 4(C) shows a printed wiring board having NSMD pads and solder bumps on the pads;

FIG. 4(D) shows a printed wiring board having NSMD pads and solder balls;

FIG. 5(A) shows a printed wiring board of Comparative Example 1;

FIG. 5(B) shows a printed wiring board of an embodiment of the present invention;

FIG. 5(C) shows a printed wiring board of Comparative Example 2;

FIG. 6(A) is a schematic view of an opening;

FIG. 6(B) is a schematic view of an upper opening portion; and

FIG. 6(C) is a schematic view of a lower opening portion.

### DETAILED DESCRIPTION OF THE EMBODIMENTS

The embodiments will now be described with reference to the accompanying drawings, wherein like reference numerals designate corresponding or identical elements throughout the various drawings.

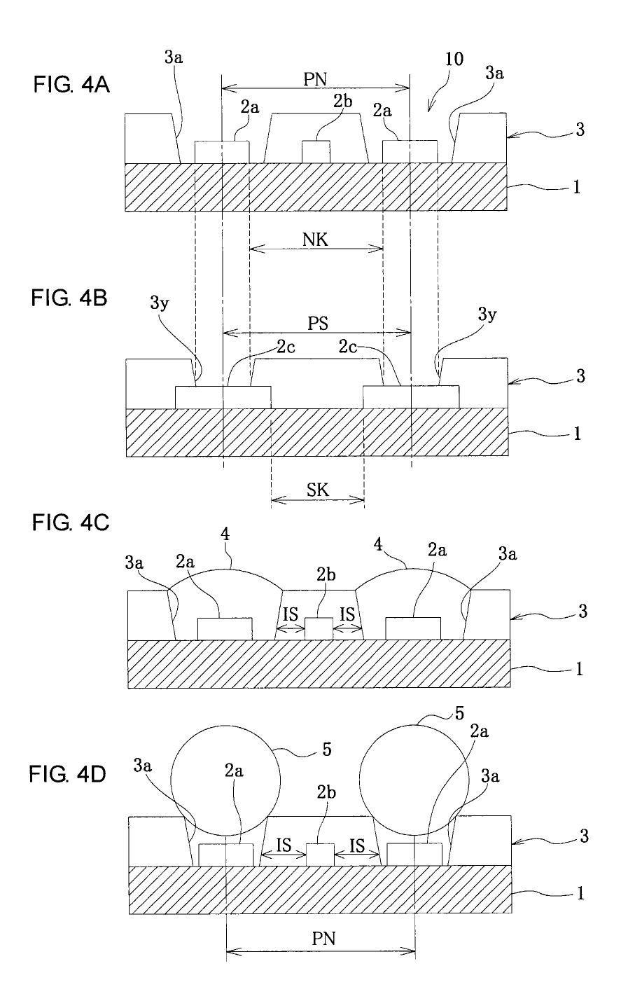

To reduce the size of a conductor for forming a pad, it is an option to employ a non-solder mask defined (NSMD) pad (2a) (see FIG. 4(A)). Regarding NSMD pad (2a), the entire pad (2a) is exposed from opening (3a) formed in solder-resist layer 3 as shown in FIG. 4(A). FIG. 4(A) shows a cross-sectional view of a printed wiring board having NSMD pad (2a), and FIG. 4(B) shows a printed wiring board having SMD pad (2c). Printed wiring board 10 shown in FIGS. 4(A) and 4(B) is formed with resin insulation layer 1, pads (2a, 2c) formed on resin insulation layer 1, and solder-resist layer 3 formed on resin insulation layer 1 and having openings (3a, 3y) to expose pads (2a, 2c) respectively. In printed wiring board 10 shown in FIGS. 4(A) and 4(B), pads (2a, 2c) have the same size, and pitches (PN, PS) between pads (2a, 2c) are set to be the same. Pitches (PN, PS) are the distances between the centers of adjacent pads.

Regarding an NSMD pad, the size of a pad is substantially equal to the size of the conductor forming the pad. Thus, when the size of the conductor for forming an SMD pad is compared with that for forming an NSMD pad, the NSMD pad has a smaller conductor size than the SMD pad. As shown in FIGS. 4(A) and 4(B), distance (NK) between the conductors for forming NSMD pads is greater than distance (SK) between the conductors for forming SMD pads. Accordingly, wiring line (2b) can be formed between adjacent NSMD pads.

FIG. 4(C) shows an NSMD-type printed wiring board having smaller pads (2a) and a narrower pitch (PN) in a highly integrated wiring board. Also, the sidewall of wiring line (2b) and the sidewall of opening (3a) are shown to have distance (IS) in FIG. 4(C). Solder bump 4 is formed in opening (3a) in FIG. 4(C). A smaller distance (IS) reduces the distance between solder bump 4 and wiring line (2b), resulting in lowered insulation reliability between solder bump 4 and wiring line (2b). To increase distance (IS), it is an option to decrease the diameter of opening (3a).

However, if opening (3a) is made smaller, solder ball 5 for forming solder bump 4 with a predetermined height cannot be placed into opening (3a) as shown in FIG. 4(D). Solder ball 5 does not make contact with pad (2a) as shown in FIG. 4(D). Thus, it is difficult to form a solder bump on pad (2a) through a reflow process. Since a solder ball with a smaller diameter reduces the height of a solder bump, it is difficult to mount an electronic component on printed wiring board 10. Connection reliability is lowered between the printed wiring board and the electronic component. It is an option to print solder in opening (3a). However, the solder in opening (3a) tends to contain voids because of the smaller diameter of opening (3a). As a result, solder bump 4 contains voids.

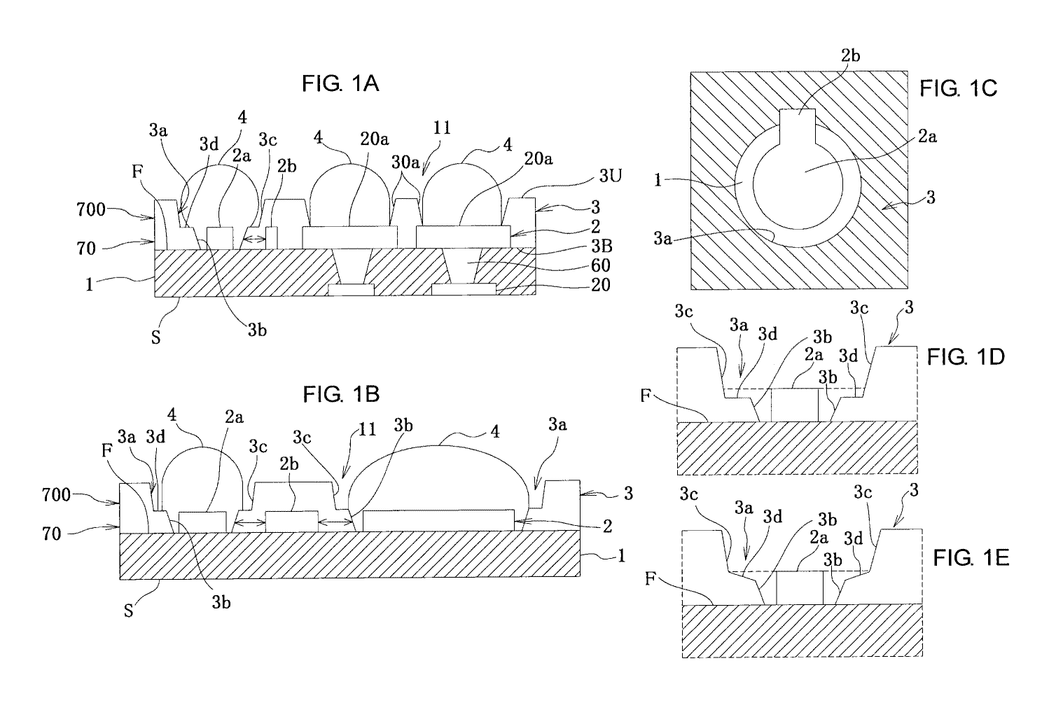

In the following, embodiments of the present invention are described with reference to the accompanying drawings. FIG. 1(A) is a cross-sectional view of a printed wiring board according to an embodiment of the present invention, and FIG. 1(B) is a cross-sectional view of a printed wiring board according to another embodiment of the present invention.

Printed wiring board 11 of an embodiment shown in FIG. 1(A) is provided with resin insulation layer 1 having first surface (F) and second surface (S) opposite the first surface, conductive layer 2 formed on first surface (F) of resin insulation layer 1, solder-resist layer 3 formed on resin insulation layer 1 and on conductive layer 2, second conductive layer 20 formed on the second surface of resin insulation layer 1, and via conductors 60 penetrating through resin insulation layer 1 and connecting conductive layer 2 and second conductive layer 20. Conductive layer 2 includes multiple pads (2a, 20a) and multiple wiring lines (2b) (only one wiring line is shown here). Solder-resist layer 3 has multiple openings (3a, 30a) to expose pads (2a, 20a) respectively.

Printed wiring board 11 shown in FIG. 1(A) has NSMD pad (2a) and SMD pad (20a). Multiple pads (2a, 20a) are densely formed in the center region (pad-forming region) of printed wiring board 11. For example, NSMD pads (2a) are formed on the peripheral portion of the pad-forming region, whereas SMD pads (20a) are formed on the central portion of the pad-forming region. Signals are transmitted through NSMD pads (2a), while power and ground go through SMD pads (20a). It is an option to form all the pads as NSMD pads (2a). FIG. 1(B) shows such a structure.

FIG. 1(C) is a plan view showing NSMD pad (2a) and opening (3a) to expose pad (2a). FIG. 1(C) is a plan view obtained by observing solder-resist layer 3 from above. When pad (2a) is an NSMD type, there is a space between pad (2a) and solder-resist layer 3. Solder-resist layer 3 does not cover pad (2a). First surface (F) of resin insulation layer 1 is exposed through the space between pad (2a) and solder-resist layer 3.

As shown in FIGS. 1(A) and 1(B), solder-resist layer 3 is made up of lower solder-resist layer 70 and upper solder-resist layer 700. In addition, opening (3a) is made up of lower opening portion (3b) and upper opening portion (3c). Lower opening portion (3b) is formed in lower solder-resist layer 70 and upper opening portion (3c) is formed in upper solder-resist layer 700. The size of upper opening portion (3c) is greater than that of lower opening portion (3b). In addition, step portion (3d) is formed between lower opening portion (3b) and upper opening portion (3c) as shown in FIGS. 1(A) and 1(B). Step portion (3d) connects upper opening portion (3c) to lower opening portion (3b).

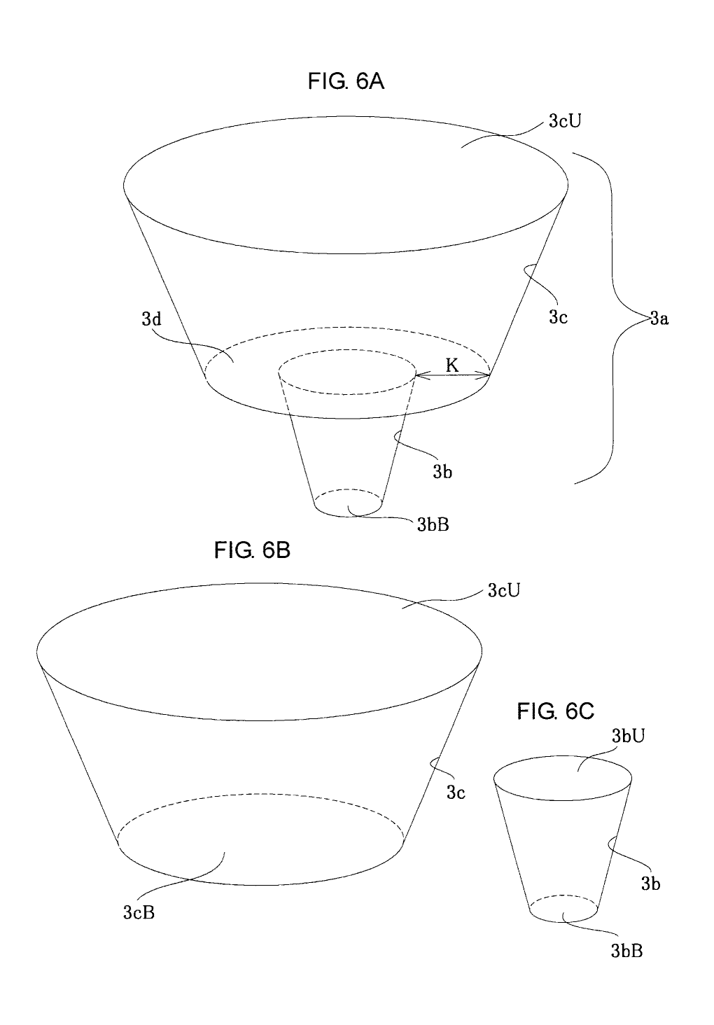

FIG. 6(B) shows upper opening portion (3c), and FIG. 6(C) shows lower opening portion (3b). As shown in FIGS. 6(B) and 6(C), upper opening portion (3c) and lower opening portion (3b) are shaped in a truncated cone; the opening portions respectively have bottom surfaces (3bB, 3cB) and top surfaces (3bU, 3cU) opposite the bottom surfaces. Sidewalls of opening portions (3b, 3c) taper from the top surface toward the bottom surface. The sidewall of lower opening portion (3b) surrounds pad (2a). FIG. 6(A) shows opening (3a), which is formed with opening portions (3b, 3c) as shown in FIGS. 6(B) and 6(C), respectively. In FIG. 6, top surfaces (3bU, 3cU) of opening portions (3b, 3c) are each set to be greater than bottom surfaces (3bB, 3cB) of opening portions (3b, 3c). In addition, bottom surface (3cB) of upper opening portion (3c) is set to overlap top surface (3bU) of lower opening portion (3b), and bottom surface (3cB) of upper opening portion (3c) is set to be greater than top surface (3bU) of lower opening portion (3b).

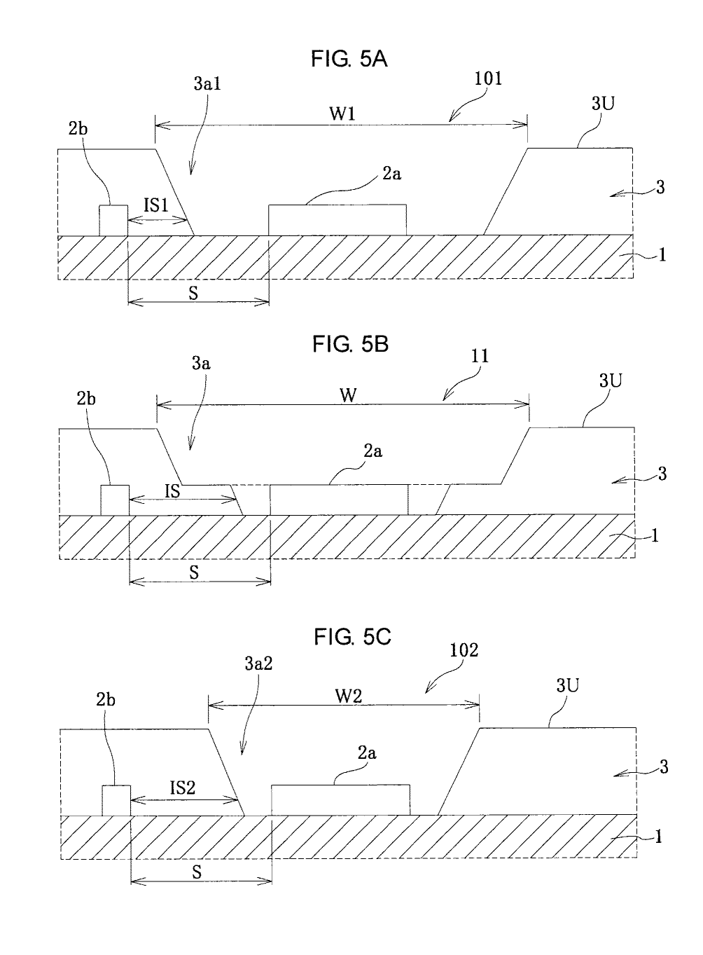

As shown in FIG. 6(A), step portion (3d) is formed between the periphery of bottom surface (3cB) of upper opening portion (3c) and the periphery of top surface (3bU) of lower opening portion (3b). Step portion (3d) belongs to the upper surface of lower solder-resist layer 70 exposed by upper opening portion (3c). Step portion (3d) is a portion of the upper surface of lower solder-resist layer 70 located between the periphery of bottom surface (3cB) of upper opening portion (3c) and the periphery of top surface (3bU) of lower opening portion (3b). Length (K) of step portion (3d) is shown in FIG. 6(A). Length (K) is set at 2.5 μm to 10 μm so as to provide a highly integrated printed wiring board. Connection reliability is high between pad (2a) and a solder bump. As shown in FIGS. 1(D) and 5(B), step portion (3d) is formed substantially parallel to the top surface of pad (2a). However, step portion (3d) may also be formed to incline relative to the top surface of pad (2a) as shown in FIG. 1(E). Step portion (3d) is preferred to be formed substantially flush with the top surface of pad (2a) as shown in FIG. 5(B). Lower surfaces of solder-resist layers (3, 70, 700) are each positioned closer to the first surface of the resin insulation layer, and their upper surfaces are positioned opposite the lower surfaces. Opening portions (3b, 3c) are each set to taper from the upper surface toward the lower surface. As shown in FIG. 1(D), step portion (3d) may be set to have a height lower than the top surface of pad (2a). Such a structure makes it easier to form a solder bump from a solder ball. The top surface of a pad is substantially parallel to first surface (F) of the resin insulation layer, but is separated from first surface (F).

FIG. 5(B) shows printed wiring board 11 of an embodiment of the present invention. FIG. 5(A) shows printed wiring board 101 of Comparative Example 1. FIG. 5(C) shows printed wiring board 102 of Comparative Example 2. Pad (2a) in each of printed wiring boards (11, 101, 102) is set to have the same size. In addition, in printed wiring boards (11, 101, 102), distance (S) between pad (2a) and wiring line (2b) is set to be the same. Printed wiring board 11 has opening (3a), printed wiring board 101 has opening (3a1), and printed wiring board 102 has opening (3a2). The sidewalls of upper opening portion (3c) and lower opening portion (3b) of opening (3a), the sidewall of opening (3a1), and the sidewall of opening (3a2) are all set to have the same inclination angle. Top surfaces (3U) of openings (3a, 3a1, 3a2) have first openings with diameters (W1, W, W2) respectively. Gaps between wiring line (2b) and the sidewall of solder-resist layer 3 are respectively referred to as gaps (IS1, IS, IS2) in printed wiring boards (11, 101, 102). If diameter (W) of the first opening of opening (3a) is the same as diameter (W1) of the first opening of opening (3a1), gap (IS) has a greater size than that of gap (IS1). Thus, when a solder bump is formed on pad (2a) of printed wiring board 11 of the embodiment, insulation reliability is high between the solder bump and wiring line (2b) in printed wiring board 11.

When gap (IS) of printed wiring board 11 is the same as gap (IS2) of printed wiring board 102, diameter (W) is greater than diameter (W2). Thus, a solder ball with a greater diameter can be placed in opening (3a) of printed wiring board 11. According to the embodiment, a solder bump is formed to have a greater height on pad (2a). By contrast, since diameter (W2) is smaller in printed wiring board 102 of Comparative Example 2, solder ball 5 used in the embodiment cannot be employed. The solder bumps are shorter in printed wiring board 102 of Comparative Example 2. When solder balls of the same size are used, solder ball 5 reaches pad (2a) in the embodiment, whereas solder ball 5 does not reach pad (2a) in Comparative Example 2. Solder bump 4 cannot be formed on pad (2a) in Comparative Example 2.

To bring solder ball 5 in contact with pad (2a), lower solder-resist layer 70 is preferred to have the same thickness as that of pad (2a), or to be thinner than pad (2a). When lower solder-resist layer 70 is set to be thinner than pad (2a), solder ball 5 unfailingly makes contact with pad (2a). Solder ball 5 forms solder bump 4 without fail. When solder paste is printed in opening (3a), no void is contained in the solder paste in opening (3a). Using printed wiring board 11, connection reliability is high between printed wiring board 11 and an electronic component mounted on printed wiring board 11.

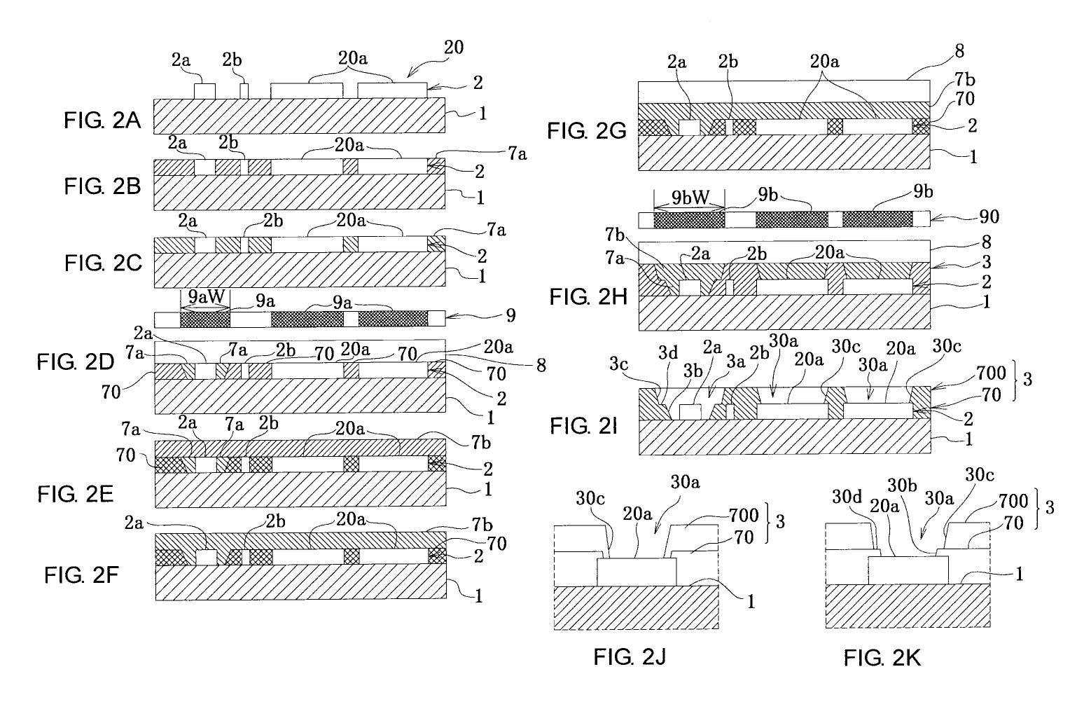

FIGS. 2(A)˜2(I) are cross-sectional views showing the manufacturing method according to a first embodiment to obtain printed wiring board 11 related to the present invention. In the method for manufacturing a printed wiring board according to the first embodiment, intermediate substrate 20 is prepared to have resin insulation layer 1 and conductive layer 2 formed on resin insulation layer 1 as shown in FIG. 2(A). Conductive layer 2 is formed by using an additive method, semi-additive method, subtractive method or the like, for example. Conductive layer 2 is made of copper, for example. Conductive layer 2 includes multiple pads (2a, 20a) for mounting electronic components such as semiconductor elements along with wiring lines (2b) as signal lines and power lines. The surface of conductive layer 2 of the intermediate substrate is roughened.

As shown in FIG. 2(B), first solder-resist composition (7a) for lower solder-resist layer 70 is formed on the resin insulation layer 1 exposed from conductive layer 2. As shown in FIG. 2(B), first solder-resist composition (7a) is filled in spaces between wiring lines (2b), spaces between pads (2a, 20a), and spaces between wiring line (2b) and pad (2a or 20a). The height (thickness) of first solder-resist composition (7a) is substantially equal to the height (thickness) of conductive layer 2.

As shown in FIG. 2(C), first solder-resist composition (7a) is dried to make it substantially tack-free.

As shown in FIG. 2(D), PET film 8 is laminated on conductive layer 2 and on first solder-resist composition (7a). At that time, the surface of first solder-resist composition (7a) is made flat.

As shown in FIG. 2(D), first exposure mask 9 with light-shielding portions (9a) is placed on first solder-resist composition (7a). Light-shielding portions (9a) are positioned on pads (2a, 20a). For forming NSMD pad (2a), the size of light-shielding portion (9a) is greater than that of pad (2a). For forming SMD pad (20a), the size of light-shielding portion (9a) is smaller than that of pad (20a). First solder-resist composition (7a) is exposed to light through first exposure mask 9. First solder-resist composition (7a) is cured so as to form lower solder-resist layer 70. Here, to form lower opening portion (3b), the first solder-resist composition (7a) that surrounds NSMD pad (2a) remains uncured. Uncured first solder-resist composition (7a) remains around pad (2a). When printed wiring board 11 has SMD pad (20a), the first solder-resist composition (7a) positioned on the SMD pad remains uncured as well. When first solder-resist composition (7a) is thicker than pads (2a, 20a), the first solder-resist composition (7a) positioned on pads (2a, 20a) will not be cured. It is an option to cure the portion of first solder-resist composition (7a) formed on the periphery of a conductive circuit for forming pad (20a).

When first solder-resist composition (7a) is removed in a subsequent process, lower solder-resist layer 70 is formed to have lower opening portions (3b). PET film 8 is removed.

As shown in FIG. 2(E), second solder-resist composition (7b) for forming upper solder-resist layer 700 is formed on lower solder-resist layer 70, first solder-resist composition (7a) and conductive layer 2. Solder-resist compositions (7a, 7b) are formed by coating. Alternatively, it is an option to form solder-resist compositions (7a, 7b) by laminating films made of solder-resist compositions (7a, 7b). Solder-resist compositions (7a, 7b) are cured by irradiating light. It is preferred to use negative-type compositions (7a, 7b). The material for second solder-resist composition (7b) may be different from the material for first solder-resist composition (7a); however, the material for second solder-resist composition (7b) is preferred to be the same as the material for first solder-resist composition (7a). In the manufacturing method according to the first embodiment, the material for second solder-resist composition (7b) is the same as the material for first solder-resist composition (7a).

As shown in FIG. 2(F), second solder-resist composition (7b) is dried to make it substantially tack-free.

As shown in FIG. 2(G), PET film 8 is laminated on second solder-resist composition (7b). At that time, the surface of second solder-resist composition (7b) is made flat.

As shown in FIG. 2(H), second exposure mask 90 with light-shielding portions (9b) is placed on second solder-resist composition (7b). Light-shielding portions (9b) are positioned on pads (2a, 20a). Shielding portion (9b) for forming NSMD pad (2a) covers first solder-resist composition (7a). In addition, light-shielding portion (9b) for forming NSMD pad (2a) is positioned on the lower solder-resist layer 70 that surrounds first solder-resist composition (7a). The size of light-shielding portion (9b) (light-shielding portion of second exposure mask 90) for forming NSMD pad (2a) is greater than that of light-shielding portion (9a) (light-shielding portion of first exposure mask 9) for forming NSMD pad (2a). Diameter (9bW) of light-shielding portion (9b) for forming NSMD pad (2a) and diameter (9aW) of light-shielding portion (9a) for forming NSMD pad (2a) are set to have a ratio (diameter (9bW)/diameter (9aW)) of 1.1 to 1.5. Under such a ratio, opening (3a) is formed to have a proper shape and proper size. Diameter (9aW) is shown in FIG. 2(D) and diameter (9bW) is shown in FIG. 2(H).

Second solder-resist composition (7b) is exposed to light through the second exposure mask to form upper solder-resist layer 700 made of second solder-resist composition (7b). Here, to form upper opening portion (3c), portions of second solder-resist composition (7b) remain uncured, namely, portions positioned on NSMD pad (2a), on first solder-resist composition (7a) surrounding pad (2a) (the first solder-resist composition in lower opening portion (3b)), and on lower solder-resist layer 70 surrounding first solder resist composition (7a) (the first solder-resist composition in lower opening portion (3b)). In addition, to form lower opening portion (3b), the first solder-resist composition (7a) that surrounds NSMD pad (2a) remains uncured. When first solder-resist composition (7a) is thicker than pad (2a) and when first solder-resist composition (7a) is present on pad (2a), the first solder-resist composition (7a) positioned on pad (2a) remains uncured.

Uncured second solder-resist composition (7b) remains on NSMD pad (2a), on uncured first solder-resist composition (7a), and on first solder-resist layer 70 surrounding uncured first solder-resist composition (7a).

When printed wiring board 11 includes SMD pad (20a), the second solder-resist composition (7b) positioned on the peripheral portion of a conductive circuit for forming pad (20a) is cured, whereas the second solder-resist composition (7b) on the central portion of the conductive circuit for forming pad (20a) remains uncured.

As shown in FIG. 2(I), PET film 8 is removed. Uncured first solder-resist composition (7a) and uncured second solder-resist composition (7b) are removed through development. On first surface (F) of resin insulation layer 1, lower solder-resist layer 70 is formed to have lower opening portion (3b) and step portion (3d). On lower solder-resist layer 70, upper solder-resist layer 700 is formed to have upper opening portion (3c) for exposing lower opening portion (3b) and step portion (3d). NSMD pad (2a) is exposed through opening (3a) made up of upper opening portion (3c) and lower opening portion (3b). Lower solder-resist layer 70 and upper solder-resist layer 700 form solder-resist layer 3. Solder-resist layer 3 has opening (30a) to expose SMD pad (20a). In the first embodiment, solder-resist layer 3 having openings (3a, 30a) is formed by a single development process.

When first solder-resist composition (7a) is set to have the same thickness as, or to be thinner than, that of a conductive circuit for forming pad (20a), opening (30a) to expose SMD pad (20a) is formed only in upper solder-resist layer 700. As shown in FIG. 2(I), pad (20a) is exposed through opening portion (30c) penetrating through upper solder-resist layer 700.

When first solder-resist composition (7a) is set to be thicker than those of pads (2a, 20a), the first solder-resist composition (7a) positioned on the peripheral portion of a conductive circuit for forming pad (20a) is cured, whereas the first solder-resist composition (7a) on the central portion of the conductive circuit for forming pad (20a) is not cured. Accordingly, lower solder-resist layer 70 to expose pad (20a) is formed on the periphery of the conductive circuit for forming pad (20a), and uncured first solder-resist composition (7a) remains on pad (20a). Then, in the process for forming second solder-resist composition (7b), second solder-resist composition (7b) is formed on lower solder-resist layer 70 on the conductive circuit for forming pad (20a) and on uncured first solder-resist composition (7a).

Then, by using second exposure mask 90 with light-shielding portion (9b) for forming SMD pad (20a), second solder-resist composition (7b) on the periphery of the conductive circuit for forming pad (20a) is cured. For forming pad (20a), the size of light-shielding portion (9b) of second exposure mask 90 is set to be smaller than that of light-shielding portion (9a) of first exposure mask 9. Thus, as shown in FIG. 2(J), upper solder-resist layer 700 on the periphery of a conductive circuit for forming pad (20a) is formed on first solder-resist layer 70 on the periphery of the conductive circuit for forming pad (20a) and on the periphery of the conductive circuit for forming pad (20a) exposed from first solder-resist layer 70. In FIG. 2(J), opening (30a) exposing SMD pad (20a) penetrates through upper solder-resist layer 700. Opening (30a) in FIG. 2(J) is made of opening portion (30c) that penetrates through upper solder-resist layer 700.

In second exposure mask 90, the aforementioned size of light-shielding portion (9b) for forming pad (20a) may be changed. For forming pad (20a), the size of light-shielding portion (9b) of second exposure mask 90 may be set greater than that of light-shielding portion (9a) of first exposure mask 9. FIG. 2(K) shows a cross-sectional view of opening (30a) in such a structure. In the example shown in FIG. 2(K), opening (30a) to expose pad (20a) is made up of opening portion (30b) penetrating through lower solder-resist layer 70 and of opening portion (30c) penetrating through upper solder-resist layer 700, the same as opening (3a) to expose pad (2a). In addition, step portion (30d) is formed between opening portion (30c) and opening portion (30b).

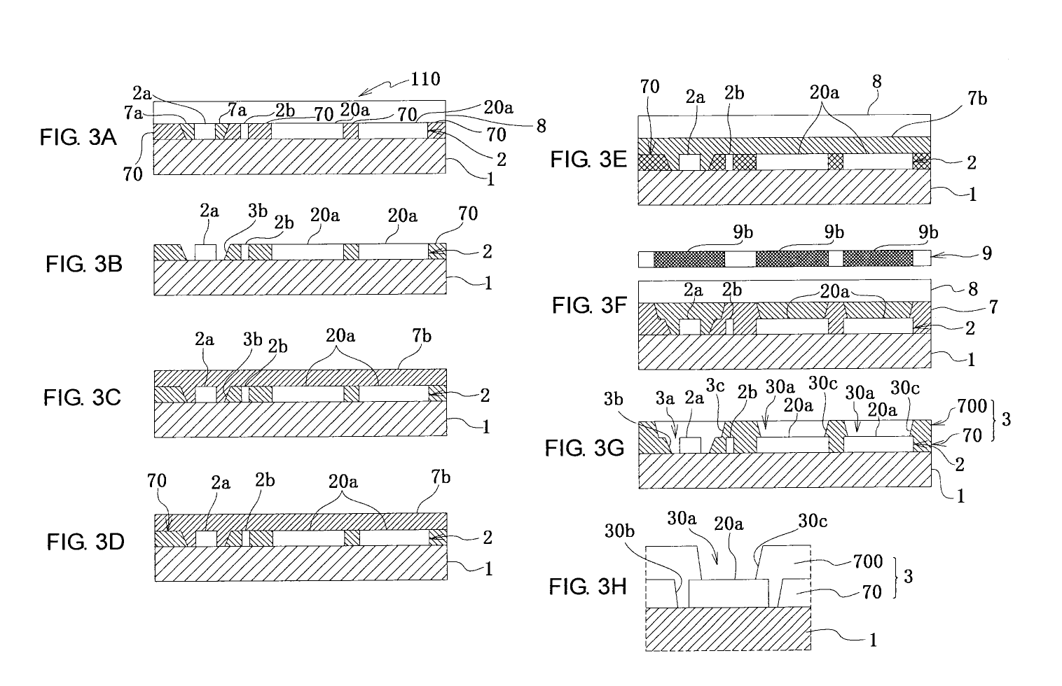

FIGS. 3(A)˜3(G) are cross-sectional views showing the manufacturing method according to a second embodiment to obtain printed wiring board 11 related to the present invention.

The same procedures as in the first embodiment are performed as shown in FIGS. 2(A)˜2(D). FIG. 3(A) shows intermediate printed wiring board 110 subsequent to the process shown in FIG. 2(D). The printed wiring board 110 in FIG. 2(D) is an intermediate substrate related to the manufacturing method of the second embodiment. Lower solder-resist layer 70 the same as in the first embodiment is formed.

Next, PET film 8 is removed. A development process is performed so that first solder-resist composition (7a) is removed from intermediate printed wiring board 110 as shown in FIG. 3(B). Since first solder-resist composition (7a) is thin, uncured first solder-resist composition (7a) is easily removed. Lower solder-resist layer 70 is formed, exposing pads (2a, 20a). Lower solder-resist layer 70 has lower opening portion (3b) to expose pad (2a). Lower solder-resist layer 70 is in contact with the sidewall of a conductive circuit for forming pad (20a).

As shown in FIG. 3(C), second solder-resist composition (7b) is formed in lower opening portion (3b), on lower solder-resist layer 70 and on pads (2a, 20a).

As shown in FIG. 3(D), second solder-resist composition (7b) is dried to make it substantially tack-free.

As shown in FIG. 3(E), PET film 8 is laminated on second solder-resist composition (7b). During that time, the surface of second solder-resist composition (7b) is made flat.

As shown in FIG. 3(F), second solder-resist composition (7b) is exposed to light. The method for an exposure-to-light process in the manufacturing method of the second embodiment is the same as that of the first embodiment. Using the same method shown in FIG. 2(H), second solder-resist composition (7b) is exposed to light.

As shown in FIG. 3(G), PET film 8 is removed. Uncured second solder-resist composition (7b) is removed through a development process. The second solder-resist composition (7b) in lower opening portion (3b) is removed. Portions of second solder-resist composition (7b) positioned on lower solder-resist layer 70, on lower opening portion (3b), and around lower opening portion (3b) are removed so that upper opening portion (3c) is formed. Lower solder resist layer 70 is formed to have lower opening portion (3b) and step portion (3d). Upper solder-resist layer 700 is formed to have upper opening portion (3c) that exposes lower opening portion (3b) and step portion (3d). Solder-resist layer 3 made of lower solder-resist layer 70 and upper solder-resist layer 700 is formed. In the manufacturing method according to the first embodiment, first solder-resist composition (7a) undergoes a drying process for first solder-resist composition (7a) and another drying process for second solder-resist composition (7b). By contrast, in the manufacturing method according to the second embodiment, first solder-resist composition (7a) is not affected by the drying process for second solder-resist composition (7b). Therefore, it is easier to remove uncured first solder-resist composition (7a) in the second embodiment.

Solder bump 4 is formed in opening (3a) of printed wiring board 11 of the embodiments shown in FIGS. 1(A) and 1(B).

When a solder-resist layer is a photocurable type, the portion of the solder-resist layer closer to first surface (F) of the resin insulation layer tends to have a lower degree of curing. A lower degree of curing reduces insulation reliability. However, according to the manufacturing methods of the first and second embodiments, lower solder-resist layer 70 is formed by exposing thin first solder-resist composition (7a). Moreover, lower solder-resist layer 70 is also exposed to light when upper solder-resist layer 700 is formed. In addition, lower solder-resist layer 70 undergoes a thermal process for second solder-resist composition (7b). Thus, by using the manufacturing methods according to the first and second embodiments, lower solder-resist layer 70 is formed to exhibit a higher degree of curing. Lower solder-resist layer 70 is filled between wiring line (2b) and pad (2a or 20a) as well as between pads (2a, 20a) and pads (2a, 20a). Since the degree of curing is high in lower solder-resist layer 70, the printed wiring board exhibits high insulation reliability.

FIG. 3(H) shows SMD pad (20a) obtained by improving the manufacturing methods of the first and second embodiments. In the example of FIG. 3(H), a conductive circuit for forming pad (20a) is completely exposed in opening portion (30b) in lower solder-resist layer 70. There is a space between the conductive circuit for forming pad (20a) and lower solder-resist layer 70. Then, the space between the conductive circuit for forming pad (20a) and lower solder-resist 70 is filled with upper solder-resist layer 700. Moreover, upper solder-resist layer 700 covers the periphery of the conductive circuit for forming pad (20a). Pad (20a) is exposed in opening portion (30c) of upper solder-resist layer 700.

Printed wiring board 11 having only NSMD pads (2a) as shown in FIG. 1(B) is manufactured by the methods according to the first and second embodiments.

By exposing solder-resist layer 3 to ultraviolet rays or by applying heat, the degree of curing of the solder-resist layer is further increased. Accordingly, the rigidity and insulation reliability of a printed wiring board are enhanced.

Lower and upper solder-resist layers (70, 700) may be formed by using either a negative or positive type. An exposure mask is selected according to the type.

In an SMD pad, a conductor forming a pad is set to have a greater size than that of the pad itself (the portion exposed in an opening of the solder-resist layer). Since the area of the conductor forming a pad is greater, the size of a printed wiring board becomes greater if it has only SMD pads.

A printed wiring board according to an embodiment of the present invention reduces the distance between a pad and its adjacent conductive circuit. A printed wiring board according to an embodiment of the present invention enhances insulation reliability between a pad and its adjacent conductive circuit. A printed wiring board according to an embodiment of the present invention makes easier to form solder bumps.

One aspect of the present invention is a printed wiring board having the following: a resin insulation layer with a first surface and a second surface opposite the first surface; a conductive layer formed on the first surface of the resin insulation layer and including an NSMD pad; and a solder-resist layer formed on the resin insulation layer and having an opening to expose the pad. The solder-resist layer is made up of a lower solder-resist layer formed on the first surface and an upper solder-resist layer formed on the lower solder-resist layer. The opening is made up of a lower opening portion formed in the lower solder-resist layer and an upper opening portion formed in the upper solder-resist layer. The upper opening portion is set to have a greater size than that of the lower opening portion.

Another aspect of the present invention is a method for manufacturing a printed wiring board including the following process: preparing an intermediate substrate having a resin insulation layer that has a first surface and a second surface opposite the first surface and a conductive layer that is formed on the first surface of the resin insulation layer and includes an NSMD pad; forming a first solder-resist composition on the first surface of the resin insulation layer exposed from the conductive layer; forming a lower solder-resist layer from the first solder-resist composition by exposing to light the first solder-resist composition in such a way to leave an uncured first solder-resist composition around the pad; forming a second solder-resist composition on the lower solder-resist layer, on the conductive layer, and on the uncured first solder-resist composition; forming an upper solder-resist layer from the second solder-resist composition by exposing to light the second solder-resist composition in such a way to leave an uncured second solder-resist composition on the uncured first solder-resist composition and on the first solder-resist layer surrounding the uncured first solder-resist composition; and forming an opening to expose the NSMD pad by removing the uncured first solder-resist composition and the uncured second solder-resist composition. The opening is made up of a lower opening portion formed in the lower solder-resist layer and an upper opening portion formed in the upper solder-resist layer, and the upper opening portion is set to have a greater size than that of the lower opening portion.

Yet another aspect of the present invention is a method for manufacturing a printed wiring board including the following process: preparing an intermediate substrate having a resin insulation layer that has a first surface and a second surface opposite the first surface, and a conductive layer that is formed on the first surface of the resin insulation layer and includes an NSMD pad; forming a first solder-resist composition on the first surface of the resin insulation layer exposed from the conductive layer; forming a lower solder-resist layer from the first solder-resist composition by exposing to light the first solder-resist composition in such a way to leave an uncured first solder-resist composition around the pad; by removing the uncured first solder-resist composition, forming a lower opening portion in the lower solder-resist layer so as to expose the NSMD pad; forming a second solder-resist composition on the lower solder-resist layer and in the lower opening portion; forming an upper solder-resist layer from the second solder-resist composition by exposing to light the second solder-resist composition in such a way to leave an uncured second solder-resist composition in the lower opening portion and on a portion of the lower solder-resist layer surrounding the lower opening portion; and by removing the uncured second solder-resist composition, forming an upper opening portion in the upper solder-resist layer to be connected to the lower opening portion. The upper opening portion is set to have a greater size than that of the lower opening portion.

Obviously, numerous modifications and variations of the present invention are possible in light of the above teachings. It is therefore to be understood that within the scope of the appended claims, the invention may be practiced otherwise than as specifically described herein.

What is claimed is:

1. A printed wiring board, comprising:
a resin insulation layer;
a conductive layer formed on a surface of the resin insulation layer and comprising a plurality of NSMD pads; and
a solder-resist layer formed on the resin insulation layer and having a plurality of openings such that the plurality of openings is exposing the plurality of NSMD pads, respectively,
wherein the solder-resist layer comprises a lower solder-resist layer formed on the surface of the resin insulation layer and an upper solder-resist layer formed on the lower solder-resist layer, and each of the openings has a lower opening portion formed in the lower solder-resist layer and an upper opening portion formed in the upper solder-resist layer such that the upper opening portion has a size which is greater than a size of the lower opening portion.

2. A printed wiring board according to claim 1, wherein the conductive layer comprises a plurality of wiring lines formed between the plurality of NSMD pads such that two adjacent NSMD pads has at least one wiring line positioned in a space formed between the two adjacent NSMD pads.

3. A printed wiring board according to claim 1, wherein the conductive layer comprises a plurality of SMD pads, and the solder-resist layer has a plurality of second openings such that the plurality of second openings is exposing the plurality of SMD pads, respectively.

4. A printed wiring board according to claim 1, wherein the conductive layer comprises a plurality of SMD pads, the solder-resist layer has a plurality of second openings such that the plurality of second openings is exposing the plurality of SMD pads, respectively, and the plurality of NSMD pads and the plurality of SMD pads are forming a pad-forming region such that the plurality of SMD pads is positioned in a central portion of the pad-forming region and the plurality of NSMD pads is positioned in a peripheral portion of the pad-forming region.

5. A printed wiring board according to claim 2, wherein the conductive layer comprises a plurality of SMD pads, the solder-resist layer has a plurality of second openings such that the plurality of second openings is exposing the plurality of SMD pads, respectively, and the plurality of NSMD pads and the plurality of SMD pads are forming a pad-forming region such that the plurality of SMD pads is positioned in a central portion of the pad-forming region and the plurality of NSMD pads is positioned in a peripheral portion of the pad-forming region.

6. A printed wiring board according to claim 1, wherein the plurality of NSMD pads is configured to transmit signal.

7. A printed wiring board according to claim 3, wherein the plurality of NSMD pads is configured to transmit signal, and the plurality of SMD pads is configured to be connected to power and ground.

8. A printed wiring board according to claim 4, wherein the plurality of NSMD pads is configured to transmit signal, and the plurality of SMD pads is configured to be connected to power and ground.

9. A printed wiring board according to claim 5, wherein the plurality of NSMD pads is configured to transmit signal, and the plurality of SMD pads is configured to be connected to power and ground.

10. A printed wiring board according to claim 1, wherein the lower solder-resist layer has a thickness which is substantially equal to or less than a thickness of the conductive layer.

11. A printed wiring board according to claim 1, wherein the upper opening portion and the lower opening portion form a step portion having a length in a range of 2.5 μm to 10 μm.

12. A printed wiring board according to claim 1, wherein the upper opening portion is formed in the upper solder-resist layer such that the upper opening portion has a diameter which is greater than a diameter of the lower opening portion in the lower solder-resist layer.

13. A method for manufacturing a printed wiring board, comprising:
forming an intermediate substrate comprising a resin insulation layer and a conductive layer such that the conductive layer is formed on a surface of the resin insulation layer and comprises a plurality of NSMD pads; and
forming a solder-resist layer on the resin insulation layer such that the solder-resist layer has a plurality of openings exposing the plurality of NSMD pads, respectively,
wherein the forming of the solder-resist layer comprises forming a lower solder-resist layer on the surface of the resin insulation layer and forming an upper solder-resist layer on the lower solder-resist layer such that each of the openings has a lower opening portion formed in the lower solder-resist layer and an upper opening portion formed in the upper solder-resist layer and having a size which is greater than a size of the lower opening portion.

14. A method for manufacturing a printed wiring board according to claim 13, wherein the forming of the solder-resist layer comprises forming a layer of a first solder-resist composition on part of the surface of the resin insulation layer exposed from the conductive layer, applying light exposure to the layer of the first solder-resist composition such that the lower solder-resist layer is formed having a plurality of uncured first solder-resist composition portions surrounding the NSMD pads, forming a layer of a second solder-resist composition on the lower solder-resist layer and the conductive layer, applying light-exposure to the layer of the second solder-resist composition such that the upper solder-resist layer is formed having a plurality of uncured second solder-resist composition portions on the uncured first solder-resist composition portions and surrounding the uncured first solder-resist composition portions, and removing the uncured first solder-resist composition portions and the uncured second solder-resist composition portions such that the plurality of openings exposing the plurality of NSMD pads is formed.

15. A method for manufacturing a printed wiring board according to claim 13, wherein the forming of the solder-resist layer comprises forming a layer of a first solder-resist composition on part of the surface of the resin insulation layer exposed from the conductive layer, applying light-exposure to the layer of the first solder-resist composition such that the lower solder-resist layer having a plurality of uncured first solder-resist composition portions surrounding NSMD pads is formed, removing the uncured first solder-resist composition portions such that the lower opening portion exposing a respective one of the NSMD pads is formed in the lower solder-resist layer, forming a layer of a second solder-resist composition on the lower solder-resist layer such that the second solder-resist composition is in the lower opening portion, applying light exposure to the layer of the second solder-resist composition such that the upper solder-resist layer is formed having a plurality of uncured second solder-resist composition portions each in the lower opening portion and surrounding the lower opening portion, and removing the uncured second solder-resist composition portions such that the upper opening portion connected to the lower opening portion is formed in the upper solder-resist layer.

16. A method for manufacturing a printed wiring board according to claim 13, wherein the forming of the intermediate substrate comprises forming the conductive layer comprising a plurality of SMD pads, and the forming of the solder-resist layer comprises forming a plurality of second openings such that the plurality of second openings is exposing the plurality of SMD pads, respectively.

17. A method for manufacturing a printed wiring board according to claim 14, wherein the forming of the intermediate substrate comprises forming the conductive layer comprising a plurality of SMD pads, and the forming of the solder-resist layer comprises forming a plurality of second openings such that the plurality of second openings is exposing the plurality of SMD pads, respectively.

18. A method for manufacturing a printed wiring board according to claim 15, wherein the forming of the intermediate substrate comprises forming the conductive layer comprising a plurality of SMD pads, and the forming of the solder-resist layer comprises forming a plurality of second openings such that the plurality of second openings is exposing the plurality of SMD pads, respectively.

19. A method for manufacturing a printed wiring board according to claim 14, wherein the forming of the intermediate substrate comprises forming the conductive layer comprising a plurality of SMD pads and the plurality of NSMD pads which form a pad-forming region such that the plurality of SMD pads is positioned in a central portion of the pad-forming region and the plurality of NSMD pads is positioned in a peripheral portion of the pad-forming region, and the forming of the solder-resist layer comprises forming a plurality of second openings such that the plurality of second openings is exposing the plurality of SMD pads, respectively.

20. A method for manufacturing a printed wiring board according to claim 15, wherein the forming of the intermediate substrate comprises forming the conductive layer comprising a plurality of SMD pads and the plurality of NSMD pads which form a pad-forming region such that the plurality of SMD pads is positioned in a central portion of the pad-forming region and the plurality of NSMD pads is positioned in a peripheral portion of the pad-forming region, and the forming of the solder-resist layer comprises forming a plurality of second openings such that the plurality of second openings is exposing the plurality of SMD pads, respectively.
